(19) United States
(12) Patent Application Publication
(10) Pub. No.: US 2025/0052623 A1
(43) Pub. Date: Feb. 13, 2025

(54) Assembly comprising a semiconductor component and a temperature sensor unit for measuring a temperature of the semiconductor component, and switch arrangement

(71) Applicant: SEG Automotive Germany GmbH, Stuttgart (DE)

(72) Inventors: Nima SAADAT, Stuttgart (DE); Andreas WINTERL, Stuttgart (DE); Mathis LURTZ, Stuttgart (DE)

(21) Appl. No.: 18/770,216

(22) Filed: Jul. 11, 2024

(30) Foreign Application Priority Data
Aug. 10, 2023 (DE) 102023121476.4

(51) Int. Cl. G01K 1/14; H01L 23/34; H01L 23/46; H01L 25/07

(52) U.S. Cl. CPC G01K 1/14; H01L 23/34; H01L 23/46; H01L 25/072

(57) ABSTRACT

An assembly includes a semiconductor component and a temperature sensor unit for measuring a temperature of the semiconductor component, wherein the semiconductor component comprises a recess, wherein the temperature sensor unit comprises a housing element and a temperature sensor element, wherein the housing element comprises a first housing section and a second housing section, wherein the second housing section protrudes from the first housing section, wherein the temperature sensor element is at least partially located in the second housing section, the second housing section projecting from the first housing section, the temperature sensor element being arranged at least partially in the second housing section, the second housing section being arranged in the recess of the semiconductor component, and a switch arrangement having at least one such assembly and at least one further semiconductor component.

### CROSS REFERENCE TO RELATED APPLICATIONS

This application claims priority to German Patent Application No. 102023121476.4 filed Aug. 10, 2023, hereby incorporated in their entirety.

### TECHNICAL FIELD

The present disclosure relates to an assembly comprising a semiconductor component and a temperature sensor unit for measuring a temperature of the semiconductor component, and to a switch arrangement comprising at least one such assembly.

### BACKGROUND

Half-bridge switch arrangements can be used in power converters, for example, as inverters for alternating conversion between DC and AC voltages. For example, such switch arrangements can be used in power converters or inverters in vehicles to convert a voltage between a DC on-board power supply and an electrical machine that can be operated with multi-phase AC voltage.

Such converters usually have one half-bridge per phase with one high-side switch and one low-side switch. Individual, discrete semiconductor components, such as individual transistors like FETs, MOSFETs, IGBTs, etc., can be used as high-side or low-side switches. Furthermore, a plurality of such half-bridges can also be connected in parallel per phase, each with a first semiconductor component and a second semiconductor component, with the first semiconductor components of these parallel-connected half-bridges forming the high-side switch and the second semiconductor components of these parallel-connected half-bridges forming the low-side switch.

Temperature sensors can be used to detect temperatures within the half bridges, for example for overtemperature protection or derating. However, the placement of such temperature sensors can often prove difficult, for example due to mechanical or spatial restrictions within the power module or due to electrical insulation distances.

### SUMMARY

Against this background, an assembly comprising a semiconductor component and a temperature sensor unit for measuring a temperature of the semiconductor component, and a switch arrangement comprising at least one such assembly with the features of the independent patent claims are proposed. Advantageous embodiments are the subject of the dependent claims and the following description.

The disclosure makes use of the measure of combining a specially designed temperature sensor unit with a (conventional) semiconductor component with a recess, in particular a through-hole, to form an assembly, whereby on the one hand a temperature sensor element is arranged in the recess and thus as close as possible to the junction and unaffected by environmental effects, and on the other hand the assembly itself is mechanically very simple and reliable. The semiconductor component with recess can, for example, be one in accordance with a TO standard (transistor outline), such as TO-3P, TO-264, TO-247, etc. The semiconductor component is in particular a discrete semiconductor switch or transistor such as a MOSFET, IGBT, etc.

The temperature sensor unit has a housing element and the temperature sensor element, wherein the housing element has a first housing section and a second housing section, wherein the second housing section projects or protrudes from the first housing section. The temperature sensor element is arranged at least partially in the second housing section. The second housing section fits into the recess, in particular it fits exactly, i.e. the second housing section and the recess are complementary, in order to keep a thermal resistance between the semiconductor component and the temperature sensor unit as small as possible. The second housing section can, for example, have a cylindrical shape in order to be complementary to a through hole.

In embodiments of the disclosure, the first housing section forms a base body of the temperature sensor unit and the second housing section forms a projection rising from the base body or projecting therefrom.

The temperature sensor element is used to measure a temperature and can, for example, comprise a thermistor, in particular with a negative temperature coefficient (NTC).

The disclosure also relates to a switch arrangement comprising at least one assembly and at least one further semiconductor component, wherein the semiconductor component of the at least one assembly and the at least one further semiconductor component are connected in parallel, or wherein the semiconductor component of the at least one assembly and the at least one further semiconductor component form a half bridge.

The at least one further semiconductor component can also be part of an assembly according to the disclosure (i.e. comprising a temperature sensor unit), but does not have to be. If several further semiconductor components are part of the switch arrangement, one or more or all of the several further semiconductor components can be part of an assembly according to the disclosure, but do not have to be.

Such a switch arrangement of several semiconductor components connected in parallel can be used as a “switch” to switch currents that exceed the current conductivity of a single semiconductor component. Such a switch arrangement may also comprise two groups of parallel-connected semiconductor components which, in embodiments of the disclosure, form a half-bridge. For example, one group can be used as a high-side switch and the other group as a low-side switch.

Embodiments and advantages of the assembly according to the disclosure and the switch arrangement according to the disclosure result from the present description in a corresponding manner.

The temperature sensor unit is expediently a modular component which can be flexibly arranged on the semiconductor component in order to detect the temperature of the respective semiconductor component. The temperature sensor unit is attached or fixed to or relative to the respective semiconductor component in such a way that the second housing section is located within the recess of the semiconductor component. As mentioned, the first housing section can, for example, form a base body. For example, the first housing section can be designed for fastening or fixing the temperature sensor unit to the semiconductor component. The second housing section is designed to accommodate the actual measurement sensor. The shape and dimensions of the second housing section are adapted in particular to the shape and dimensions of the recess. The housing element can, for example, be made of a plastic and manufactured using a plastic injection molding process.

It is expedient to be able to flexibly select on which specific semiconductor component or on which specific semiconductor components of the switch arrangement a corresponding temperature sensor unit is arranged in each case, e.g. depending on a temperature distribution, a maximum temperature and/or a minimum temperature of the switch arrangement.

The disclosure thus provides a way of conveniently arranging the temperature sensor directly or in the immediate vicinity of the respective semiconductor component in a structurally simple and space-saving manner, so that this sensor can reliably and precisely detect the temperature of the semiconductor component, for example for overtemperature protection or for power reduction. The temperature sensor element can usefully be placed as close as possible or as close as necessary relative to the semiconductor component. The temperature sensor unit, in particular the shape and dimensions of the housing element, can be adapted to the conditions and space available or to mechanical or spatial restrictions within a respective power module comprising the switch arrangement. The recess can, for example, completely penetrate the semiconductor component and conventionally be provided for mechanical fastening, e.g. by means of screws, bolts, etc. This recess, which is in particular already present in the semiconductor component, is now used to position the temperature sensor. In this way, the temperature sensor can be brought very close to the junction of the semiconductor component so that any deviations in the measured temperature from the actual junction temperature can be easily compensated for, for example using software. Furthermore, the temperature sensor element can be electrically insulated by placing it inside the housing element, in particular from high-voltage potentials of the switch arrangement.

Traditionally, temperature sensors are often arranged on a housing of a respective power module, which can, however, be associated with a complicated and costly fastening of the sensors. Furthermore, such an arrangement can make it difficult to secure the sensor connections and protect the sensors from mechanical or environmental hazards. In contrast, the present temperature sensor unit can be arranged on a semiconductor component in an uncomplicated manner, which provides protection against mechanical or environmental influences. Furthermore, the temperature sensor unit makes it easy to secure the connections of the temperature sensor element.

According to one embodiment, the temperature sensor unit also has at least two electrical conductor elements. Each of the electrical conductor elements has a first conductor section and a second conductor section. The respective first conductor section is arranged within the first housing section and is electrically connected to the temperature sensor element. The respective second conductor section protrudes from the first housing section. These conductor elements are thus provided in particular as electrical terminals for the temperature sensor element. Conveniently, two such conductor elements can be provided.

The first conductor sections for electrical contacting of the sensor element can thus be arranged inside the housing element in a structurally simple and space-saving manner, which in particular provides protection against external influences and electrical insulation. By arranging the temperature sensor and the first conductor sections connected to it inside the housing element, they can be electrically insulated from the high-voltage potentials of the semiconductor components in particular.

The second conductor sections can protrude from the first housing section, for example as terminals in the form of pins or pins. In particular, the second conductor sections can be provided for connecting the temperature sensor element to a power source and/or to a computing unit for evaluating the recorded sensor values.

For example, electrical connections or terminals of the temperature sensor element can be guided or passed from the second housing section into the first housing section in order to be electrically connected there to the first conductor sections. For example, to manufacture the temperature sensor unit, the temperature sensor element can first be connected to the conductor elements and the housing element can then be formed around the unit comprising the temperature sensor element and conductor elements, e.g. by an injection molding process. Alternatively, the housing element can also be produced first, e.g. by an injection molding process, and then the temperature sensor element and the conductor elements can be inserted into the housing element and, if necessary, potted there.

According to one embodiment, the semiconductor component also has at least two electrical terminals. The second conductor sections are then oriented parallel or at least substantially parallel to the terminals of the semiconductor component. The terminals of the semiconductor component can, for example, comprise a drain, source and gate terminals (or collector/base/emitter) and also, for example, a Kelvin terminal (also referred to as Kelvin source terminal or auxiliary source terminal). The individual terminals of the semiconductor components can each be designed in particular as a pin. The second conductor sections and the terminals of the semiconductor component can in particular be arranged adjacent to each other or directly next to each other. In this way, a connection of the second conductor sections to other elements and thus a connection of the temperature sensor element, e.g. to a power source and/or a computing unit, can be made possible in a simple manner. The second conductor sections can be electrically connected to further elements of the switch arrangement corresponding to or together with the terminals of the semiconductor component.

According to one embodiment, the second conductor sections of the temperature sensor unit are each electrically connected to a control board or a printed circuit board of the switch arrangement, e.g. by a soldered or sintered connection. It is also expedient for individual or several of the terminals of the semiconductor component to be connected to this control board, in particular also by a soldered or sintered connection. In particular, the control board is provided for controlling the semiconductor components, e.g. in order to transmit control signals to the individual semiconductor components. For this purpose, the control board can be connected to a computing or control unit. In particular, the temperature sensor element can be connected to this computing unit by means of the second conductor sections and the control board in order to transmit the detected sensor values to the computing unit. Conveniently, the second conductor sections can be electrically connected to the control board together with the terminals of the semiconductor component, which can significantly simplify the contacting of the temperature sensor element. A length of the second conductor sections can conveniently be adapted depending on the position of the control board, so that the connection to the control board can be established in a simple manner.

According to one embodiment, a main extension plane of the control board is oriented perpendicularly or at least substantially perpendicularly to a main extension plane of the individual semiconductor components. Individual or several terminals of the individual semiconductor components of the switch arrangement are each connected to the control board. Since the terminals are in each case oriented in particular parallel to the main extension plane of the respective semiconductor component, the terminals are expediently also oriented perpendicularly or at least essentially perpendicularly to the control board. Accordingly, the second conductor sections of the temperature sensor unit are also appropriately oriented perpendicularly or at least essentially perpendicularly to the control board.

In particular, the respective terminals of the semiconductor components and the second conductor sections can each be designed as a pin and can be contacted with the control board by means of through-hole technology (THT) or pin-in-hole technology (PIH). For this purpose, the respective pin penetrates the control board, for example through a corresponding connection opening, in particular in the form of a hole or bore, and is connected to the control board by a material bond, in particular by a soldered or sintered connection. This makes it easy to establish contact with the temperature sensor element. The temperature sensor unit is therefore a useful integrated temperature sensor for through-hole mounting (THT) or for semiconductor components connected to circuit boards or printed circuit boards by means of THT.

According to one embodiment, the conductor elements are each designed as strips or tapes, in particular as copper strips. A length of these individual strips can be adapted to the specific circumstances, e.g. depending on the size and shape of the first housing section, depending on a distance between the first housing section and the control board, etc.

According to one embodiment, the temperature sensor unit also has at least one mechanical connecting element which is set up to be mechanically connected to a carrier for the semiconductor component, in particular to a heat sink on which the semiconductor component is mounted, for example a heat sink of the switch arrangement. For example, each mechanical connecting element can be designed as a projection, pin, bolt, latching hook or the like, which can be inserted into a corresponding recess or opening in the carrier.

According to one embodiment, the at least one mechanical connecting element connects to the first housing section at a predetermined angle. For example, the connecting elements can each be designed as a projection, pin, latching hook or bolt that adjoins the first housing section at a right angle.

According to one embodiment, a main direction of extension of the at least one mechanical connecting element is oriented parallel or at least substantially parallel to a main direction of extension of the second housing section. In particular, the at least one mechanical connecting element and the second housing section are arranged on the same side of the first housing section, expediently on that side which is turned towards the respective semiconductor component. The second housing section can thus be inserted into recesses of the respective semiconductor component and, at the same time, the at least one mechanical connecting element can be inserted into a corresponding opening of the carrier on which the respective semiconductor component is arranged.

According to one embodiment, the switch arrangement also has a heat sink, whereby the individual semiconductor components are each arranged on a side surface or on several side surfaces of the heat sink. The individual semiconductor components are in thermal contact with the heat sink. The heat sink is expediently provided for dissipating waste heat from the individual semiconductor components. For example, the heat sink can be fluid-cooled and have, for example, an inlet and outlet for a corresponding cooling fluid. The cooling fluid can include oil, water, air, etc., for example. Expediently, the individual semiconductor components are each arranged relative to the heat sink in such a way that the respective main extension plane of the individual semiconductor components is each arranged parallel or at least substantially parallel to the respective side surface of the heat sink. Conveniently, the control board is arranged perpendicularly or at least substantially perpendicularly to the side surfaces of the heat sink.

For example, all semiconductor components can be arranged together on a single side surface of the heat sink. Furthermore, a first number of the semiconductor components, e.g. all semiconductor components used as high-side switches, can also be arranged on a first side surface of the heat sink and a second number of the semiconductor components, e.g. all semiconductor components used as low-side switches, can be arranged on a second side surface of the heat sink. This first side surface and this second side surface can, for example, be opposite or facing away from each other or opposite side surfaces of the heat sink.

In particular, the individual semiconductor components are each electrically insulated from the heat sink by an electrical semiconductor component insulating layer. These semiconductor component insulating layers each represent in particular a thermal interface material (TIM) between the respective semiconductor component and the heat sink and can each have a low thermal resistance or a high thermal conductivity. In this way, thermal resistance between the individual semiconductor components and the heat sink can be reduced so that heat can be effectively dissipated from the semiconductor components to the heat sink. For example, the semiconductor component insulating layers can each be made of metallized ceramic and/or a ceramic material, e.g. aluminium oxide (Al₂O₃), aluminium nitride (AlN) or silicon nitride (Si₃N₄).

According to one embodiment, the at least one mechanical connecting element of the temperature sensor unit is designed to be mechanically connected to the heat sink of the switch arrangement. For this purpose, the heat sink has, for example, a corresponding opening into which the respective connecting element can be inserted. Since the respective semiconductor component is arranged in particular directly or in the immediate vicinity of the heat sink, it is suitable to attach the temperature sensor unit to the heat sink in this way.

According to one embodiment, a temperature sensor unit is arranged on each of two of the semiconductor components of a switch arrangement, wherein these two semiconductor components are arranged at opposite ends of the respective side surface of the heat sink. In particular, these two semiconductor components can be arranged at opposite ends of the respective side surface with respect to a flow direction of a cooling fluid through the heat sink. For example, a fluid inlet for the cooling fluid may be arranged in the vicinity of a first end of the respective side surface and a fluid outlet for the cooling fluid may be arranged in the vicinity of the opposite second end. The semiconductor component which is arranged at the first end of the side surface near the fluid inlet is in particular the best cooled semiconductor component with the lowest temperature of the semiconductor components arranged at this side surface. Correspondingly, the semiconductor component arranged at the second end of the side surface near the fluid outlet is in particular the worst cooled semiconductor component with the highest temperature of the semiconductor components arranged at this side surface. With the aid of the temperature sensor units arranged on these two semiconductor components, a maximum and minimum temperature of the semiconductor components arranged on this side surface can thus be detected. The temperatures of the remaining semiconductor components arranged on this side surface can be conveniently estimated or interpolated depending on the maximum and minimum temperature detected. If a number of semiconductor components are arranged on several side surfaces of the heat sink, a temperature sensor unit can be arranged on the two semiconductor components which are arranged at the opposite ends of the respective side surface.

According to one embodiment, the switch arrangement has at least one clamping element that is set up to press one or more of the semiconductor components against the heat sink. For example, a separate clamping element can be provided for each of the individual semiconductor components or a common clamping element can also be provided for several of the semiconductor components. For example, if the semiconductor components are arranged on two different side surfaces of the heat sink, a first clamping element can be provided for the first side surface of the heat sink in order to press the semiconductor components arranged there against this first side surface, and a second clamping element can be provided for the second side surface in order to press the semiconductor components arranged there against this second side surface. With the aid of these clamping elements, the individual semiconductor components can be frictionally connected to the heat sink, in particular in a manner that is easy to release. The respective recess in the individual semiconductor components, which can conventionally be provided for fastening by means of screws or bolts, is therefore expediently not required for fastening the semiconductor component to the heat sink and can be used to accommodate the second housing section and thus the temperature sensor element.

The switch arrangement is suitable for use in a vehicle, expediently for converting a voltage between a DC on-board power supply and an electrical machine that can be operated with a multi-phase AC voltage. The switch arrangement can, for example, be part of a power converter or inverter for controlling several phases of the electrical machine, wherein, for example, a half-bridge is provided for controlling one phase at a time.

In a half-bridge switch arrangement, a plurality of semiconductor components are arranged on a heat sink and printed circuit boards or control boards can be arranged perpendicular to the heat sink. The disclosed temperature sensor unit can be arranged on one or more of these semiconductor components.

Further advantages and embodiments of the disclosure are shown in the description and the accompanying drawing.

The disclosure is illustrated schematically in the drawing by means of embodiment examples and is described below with reference to the drawing.

### BRIEF DESCRIPTION OF THE DRAWINGS

FIGS. 1a-1e schematically show an embodiment of a temperature sensor unit for use in an assembly according to the disclosure.

FIGS. 2a-2b schematically show an embodiment of another temperature sensor unit for use in an assembly according to the disclosure.

FIG. 3 schematically shows an embodiment of a switch arrangement according to the disclosure with two assemblies according to embodiments of the disclosure.

### DETAILED DESCRIPTION

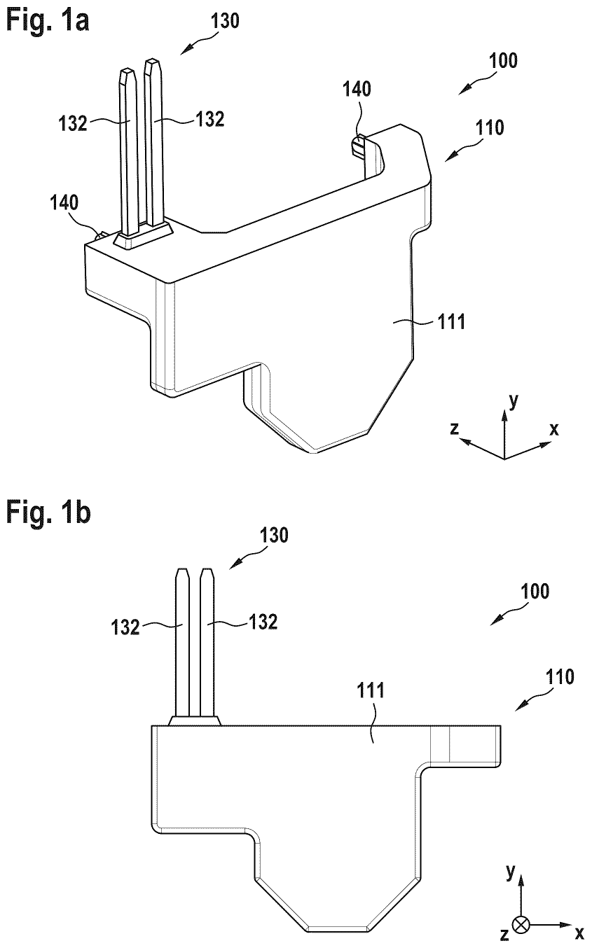

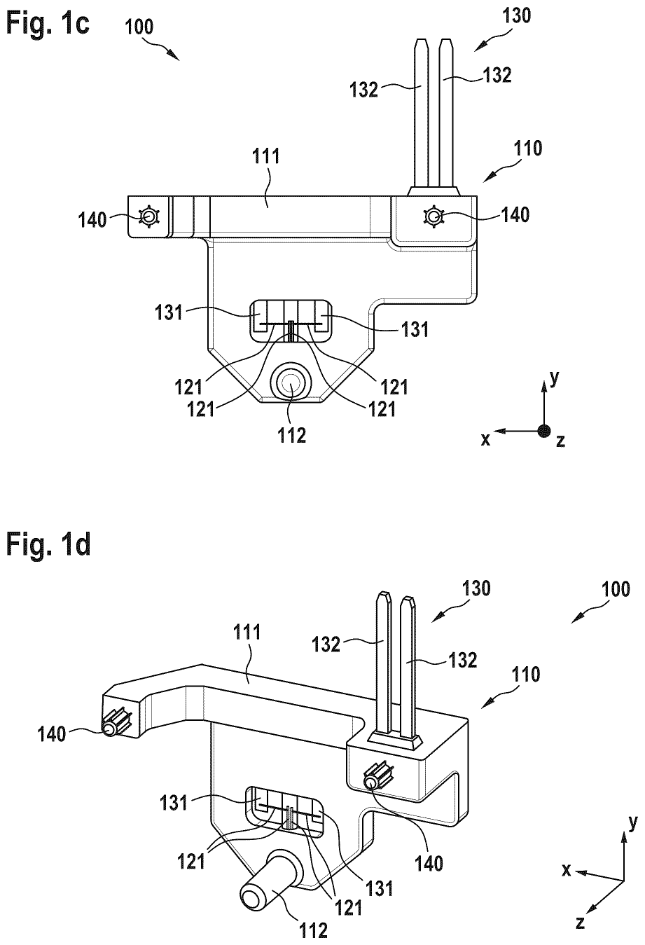

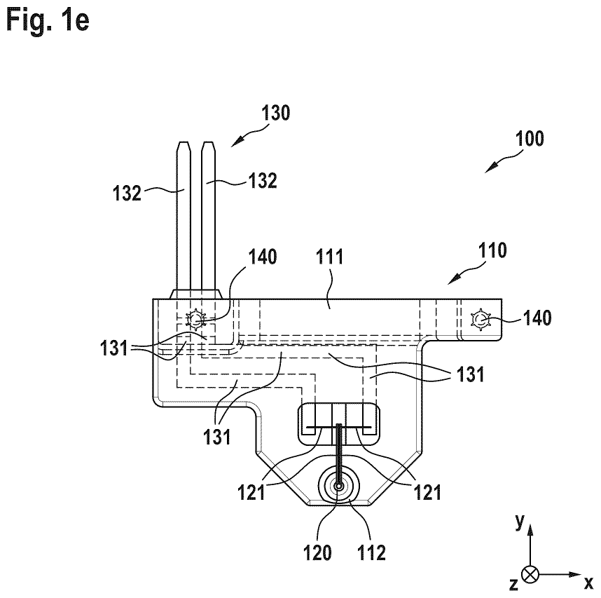

In FIGS. 1a-1e, a temperature sensor unit 100 for use in an assembly according to the disclosure is shown schematically in various views. FIGS. 1a and 1d each show the temperature sensor unit 100 in a perspective view, FIG. 1b in a front view and 1c in a rear view. Like FIG. 1b, FIG. 1e shows the temperature sensor unit 100 in a front view, but in a transparent view, so that elements inside the temperature sensor unit 100 are also shown.

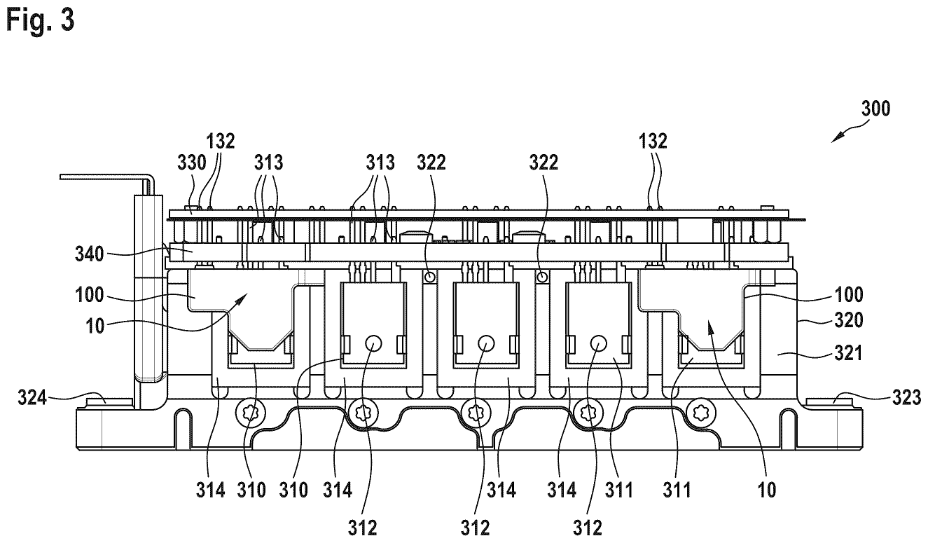

The temperature sensor unit 100 is configured for measuring a temperature of a semiconductor component in an assembly, e.g. a metal-oxide-semiconductor field-effect transistor (MOSFET) or an insulated-gate bipolar transistor (IGBT). This semiconductor component has a surface and a recess extending from the surface into the semiconductor component (see FIG. 3).

The temperature sensor unit 100 has a housing element 110 with a first housing section 111 and a second housing section 112, wherein a main extension plane of the first housing section 111 is oriented at a predetermined angle to a main extension direction of the second housing section 112. In the example shown in FIGS. 1a-1e, the main extension plane of the first housing section 111 runs parallel to that of the x-y plane and the main extension direction of the second housing section 112 runs parallel to the z direction. The main extension plane of the first housing section 111 and the main extension direction of the second housing section 112 are thus oriented at right angles to each other. For example, the second housing section 112 is cylindrical in shape.

The temperature sensor unit 100 further comprises a temperature sensor element 120, for example a thermistor with a negative temperature coefficient (NTC). The temperature sensor element 120 is arranged at least partially in the second housing section 112. For example, a measurement sensor system of the temperature sensor element 120 is arranged within the second housing section 112. Electrical connections 121 of the temperature sensor element 120 protrude, for example, from the second housing section 112 into the first housing section 111.

The second housing section 112 is adapted to be inserted into the recess of the semiconductor component. In this way, the temperature sensing element 120 can be inserted directly into the semiconductor component to sense the temperature within the semiconductor component.

The temperature sensor unit 100 further comprises conductor elements 130, each having a first conductor section 131 and a second conductor section 132, wherein the respective first conductor section 131 is arranged within the first housing section 111 and is electrically connected to the temperature sensor element 120, respectively, and wherein the respective second conductor section 132 protrudes from the first housing section 111. For example, the electrical connections 121 of the temperature sensor element 120, which project from the second housing section 112 into the first housing section 111, are electrically connected to the first conductor sections 131, for example by a soldered connection. The second conductor sections 132 protrude from the first housing section 111, for example as connections in the form of pins. In particular, the second conductor sections 132 run parallel to the main extension plane of the first housing section 111 and thus also parallel to the x-y plane. For example, the conductor elements 130 can each be formed as copper bands or copper strips.

The housing element 110 is made of a plastic, for example, and is manufactured using a plastic injection molding process, for example. By arranging the temperature sensor element 120 and the first conductor sections 131 within the housing element 110, these can be electrically insulated, in particular from high-voltage potentials of the semiconductor component.

The temperature sensor unit 100 also has two mechanical connecting elements 140, which are designed to be mechanically connected to a carrier for the semiconductor component, for example to a heat sink. For example, these mechanical connecting elements 140 are each designed as a projection, pin, latching hook or bolt. The two mechanical connecting elements 140 each connect to the first housing section 111 at a predetermined angle, in particular at right angles. A main direction of extension of each mechanical connecting element 140 is oriented parallel to the main direction of extension of the second housing section 112 and thus runs in the z-direction.

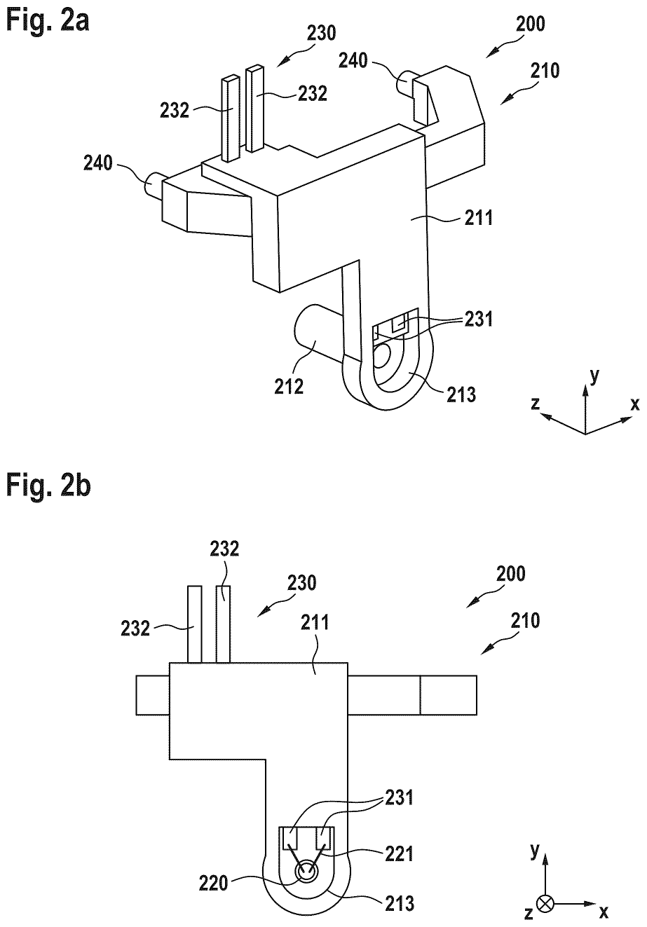

FIGS. 2a-2b also show a schematic embodiment of a temperature sensor unit 200 that can be used within the scope of the disclosure, in FIG. 2a in a perspective view, in FIG. 2b in a plan view. Identical or structurally identical elements of the temperature sensor unit 200 shown in FIGS. 2a-2b are each provided with a reference sign which is increased by the value 100 in comparison with the temperature sensor unit 100 from FIGS. 1a-1e.

In contrast to the temperature sensor unit 100 of FIGS. 1a-1e, the temperature sensor unit 200 of FIGS. 2a-2b has an opening 213 in the first housing section 211. Through this opening 213, the temperature sensor element 220 can be easily inserted into the second housing section 212 and, if necessary, removed or replaced again. Furthermore, the connections 221 of the temperature sensor element 220 can be connected to the first conductor sections 231 through the opening 213. The opening 213 serves to accommodate a temperature sensor element.

In FIG. 3, an embodiment of a switch arrangement according to the disclosure is shown in a schematic side view and labeled 300, wherein the switch arrangement 300 comprises a plurality of the temperature sensor units 100 shown in FIGS. 1a-1e as parts of assemblies 10 according to embodiments of the disclosure. Each of the two assemblies 10 has a semiconductor component 310 and a temperature sensor unit 100 for measuring a temperature of the semiconductor component 310.

The switch arrangement 300 is intended, for example, for use in a vehicle in order to convert a voltage between a DC on-board power supply and an electrical machine that can be operated with a polyphase AC voltage.

The switch arrangement 300 has a plurality of semiconductor components 310, two of which are part of an assembly 10 (i.e. connected to a temperature sensor unit) and three of which are not. The individual semiconductor components 310 are each formed, for example, as a MOSFET and each have a surface 311 and a recess 312 extending from the surface 311 and extending into the semiconductor component 310. Furthermore, the semiconductor components 310 each have a plurality of terminals 313, in particular a drain, source, gate and Kelvin terminal in each case.

The switch arrangement 300 further comprises a heat sink 320, wherein the individual semiconductor components 310 are each arranged on a side surface or on several side surfaces of the heat sink 320. In the schematic side view of FIG. 3, a first side surface 321 of the heat sink 320 can be seen, on which five semiconductor components 310 are arranged. For example, five semiconductor components 310 are also arranged in a corresponding manner on a second side surface opposite the first side surface 321, which is not shown in FIG. 3. For example, semiconductor components 310 located opposite each other on the two side surfaces each form a half bridge.

In such a case, switch arrangement 300 thus has five half-bridges, with these five half-bridges being connected in parallel, for example. For example, the semiconductor components 310 arranged on the first side surface 321 can be used together as a low-side switch and the semiconductor components 310 arranged on the second side surface can be used together as a high-side switch. For example, the switch arrangement 300 is thus designed as a phase half-bridge for controlling one phase of the electrical machine. In a multi-phase inverter of the vehicle, several such switch arrangements 300 can be provided, e.g. three switch arrangements 300 for a three-phase electrical machine. Alternatively, the half-bridges can also be operated individually, so that five phases, or three phases and two other currents, can also be switched with a switch arrangement 300 with five half-bridges as shown.

The individual semiconductor components 310 are each in thermal contact with the heat sink 320 and are each thermally insulated from the heat sink 320 by a semiconductor component insulating layer 314. These semiconductor component insulating layers 314 each represent a thermal interface material (TIM) between the respective semiconductor component 310 and the heat sink 320 and each have a low thermal resistance or a high thermal conductivity. For example, the semiconductor component insulating layers are each made of metallized ceramic and/or a ceramic material, e.g. aluminium oxide (Al₂O₃), aluminium nitride (AlN) or silicon nitride (Si₃N₄).

A thermal resistance between the individual semiconductor components 310 and the heat sink 320 can thus be reduced, so that heat can be effectively dissipated from the semiconductor components 310 to the heat sink 320. For example, the heat sink 320 may be fluid cooled and have an inlet 323 for supplying a cooling fluid and an outlet 324 for discharging the cooling fluid. The cooling fluid may include, for example, oil, water, air, etc.

The individual semiconductor components 310 are each arranged relative to the heat sink 320 such that the respective surface 311 of the individual semiconductor components 310 is each arranged parallel or at least substantially parallel to the respective side surface 321 of the heat sink 320.

The switch arrangement 300 further comprises a control board 330 and a printed circuit board 340. A main extension plane of the control board 330 is oriented perpendicular to the respective surface 311 of the individual semiconductor components 310 and thus perpendicular to the side surface 321 of the heat sink 320. Furthermore, the main extension plane of the control board 330 is oriented parallel to a main extension plane of the printed circuit board 340. The control board 330 may be provided for transmitting and receiving logic signals, in particular for driving the individual semiconductor components 310. The printed circuit board 340 may, for example, be designed as a multilayer board, wherein individual layers of the printed circuit board 340 may be provided as busbars for energizing the semiconductor components 310.

Individual terminals 313 of the semiconductor components 310, in particular the respective gate and Kelvin terminals, are electrically connected to the control board 330, in particular in each case by means of through-hole technology (THT). The remaining terminals 313 of the semiconductor components 310, in particular the respective drain and source terminals, are electrically connected to the printed circuit board 340, in particular also in each case by means of through-hole technology (THT).

A temperature sensor unit 100 is arranged on a plurality of the semiconductor components 310, as shown in FIGS. 1a-1e. The respective second housing section 112 of the respective temperature sensor unit 100 is inserted into the recess 312 of the respective semiconductor component 310. Furthermore, the respective mechanical connecting elements 140 of the respective temperature sensor unit 100 are mechanically connected to the heat sink 320. For this purpose, the connecting elements 140 are each inserted into corresponding recesses 322 in the heat sink 320.

As shown in FIG. 3, for example, a temperature sensor unit 100 is arranged on each of two of the semiconductor components 310 arranged on the first side surface 321. For example, these semiconductor components 310 are arranged at the opposite ends of the side surface 321, in particular with respect to a flow direction of the cooling fluid. For example, the right semiconductor component 310 in FIG. 3 is arranged near the fluid inlet 323 and is thus, for example, the best cooled semiconductor component with the lowest temperature of the five semiconductor components 310 arranged on the first side surface 321. Accordingly, the left semiconductor component 310 in FIG. 3 is arranged near the fluid outlet 324 and is thus the worst cooled semiconductor component with the highest temperature of the five semiconductor components 310 arranged on the side surface 321. Thus, a maximum and minimum temperature of the five semiconductor components 310 arranged on the side surface 321 can be detected by means of the temperature sensor units 100 arranged on these two semiconductor components 310. The temperatures of the remaining three semiconductor components 310 arranged on the side surface 321 can be estimated depending on this detected maximum and minimum temperature. In a corresponding manner, for example, two temperature sensor units 100 may also be arranged on the semiconductor components arranged on the opposite side surface of the heat sink 320.

The temperature sensor units 100 are each arranged relative to the respective semiconductor component 310 such that the main extension plane of the respective first housing section 111 is oriented parallel to the respective surface 311 of the respective semiconductor component 310. Further, the respective second conductor sections 132 of the temperature sensor units 100 are each oriented parallel to the terminals 313 of the respective semiconductor component 310. The second conductor sections 132 of the temperature sensor units 310 are each electrically connected to the control board 330 by means of through-hole mounting THT. The second conductor sections 132 are electrically insulated from the printed circuit board 340, for example.

The present disclosure thus provides a way of arranging temperature sensors in a structurally simple and space-saving manner directly or in the immediate vicinity of semiconductor components of the switch arrangement, so that this sensor can reliably and precisely detect the temperature of the semiconductor component. In this way, the respective temperature sensor can be brought very close to the junction of the semiconductor component, so that any deviations of the measured temperature from the actual junction temperature can be easily compensated for, for example by means of software. The temperature sensor unit is useful as an integrated temperature sensor for through-hole mounting (THT) or for semiconductor components connected to circuit boards or printed circuit boards by means of THT.

What is claimed is:

1. An assembly (10) comprising a semiconductor component (310) and a temperature sensor unit (100, 200) for measuring a temperature of the semiconductor component (310),
wherein the semiconductor component (310) has a recess (312),
wherein the temperature sensor unit (100, 200) comprises a housing element (110, 210) and a temperature sensor element (120, 220),
wherein the housing element (110, 210) comprises a first housing section (111, 211) and a second housing section (112, 212), wherein the second housing section (112, 212) projects from the first housing section (111, 211),
wherein the temperature sensor element (120, 220) is arranged at least partially in the second housing section (111, 211),
wherein the second housing section (112, 212) is arranged in the recess (312) of the semiconductor component (310).

2. The assembly (10) according to claim 1, wherein the temperature sensor unit (100, 200) comprises at least two electrical conductor elements (130, 230), wherein each of the at least two electrical conductor elements (130, 230) comprises a first conductor section (131, 231) and a second conductor section (132, 232), wherein the respective first conductor section (131, 231) is arranged within the first housing section (111, 211) and is electrically connected to the temperature sensor element (120, 220), and wherein the respective second conductor section (132, 232) projects out of the first housing section (111, 211).

3. The assembly (10) according to claim 2, wherein the semiconductor component (310) comprises at least two terminals (313), wherein the second conductor sections (132, 232) of the temperature sensor unit (100, 200) are oriented parallel or at least substantially parallel to the terminals (313) of the semiconductor component (310).

4. The assembly (10) according to claim 2, wherein the at least two electrical conductor elements (130, 230) are each formed as tapes or strips, in particular as copper tapes.

5. The assembly (10) according claim 1, wherein the temperature sensor unit (100, 200) comprises at least one mechanical connecting element (140, 240) adapted to be mechanically connected to a support for the semiconductor component (310), in particular to a heat sink (320) on which the semiconductor component (310) is mounted.

6. The assembly (10) according to claim 5, wherein the at least one mechanical connecting element (140, 240) connects to the first housing section (111, 211) at a predetermined angle and/or wherein a main extension direction of the at least one mechanical connecting element (140, 240) is oriented parallel or at least substantially parallel to a main extension direction of the second housing section (112, 212).

7. A switch arrangement (300) comprising at least one assembly (10) according to claim 1 and at least one further semiconductor component,
wherein the semiconductor component (310) of the at least one assembly and the at least one further semiconductor component are connected in parallel, or
wherein the semiconductor component (310) of the at least one assembly and the at least one further semiconductor component form a half bridge.

8. The switch arrangement (300) according to claim 7, further comprising a heat sink (320) as a carrier, wherein the semiconductor component (310) of the assembly and the further semiconductor component are arranged on the heat sink (320).

9. The switch arrangement (300) according to claim 8, wherein the temperature sensor unit (100, 200) comprises at least one mechanical connecting element (140, 240) adapted to be mechanically connected to a support for the semiconductor component (310) of the assembly, in particular to a heat sink (320) on which the semiconductor component (310) of the assembly is mounted, wherein the at least one mechanical connecting element (140, 240) of the assembly is mechanically connected to the heat sink (320).

10. The switch arrangement (300) according to claim 8, comprising at least two assemblies (10), each assembly comprising:
a semiconductor component (310) and a temperature sensor unit (100, 200) for measuring a temperature of the semiconductor component (310),
wherein the semiconductor component (310) has a recess (312),
wherein the temperature sensor unit (100, 200) comprises a housing element (110, 210) and a temperature sensor element (120, 220),
wherein the housing element (110, 210) comprises a first housing section (111, 211) and a second housing section (112, 212), wherein the second housing section (112, 212) projects from the first housing section (111, 211),
wherein the temperature sensor element (120, 220) is arranged at least partially in the second housing section (111, 211),
wherein the second housing section (112, 212) is arranged in the recess (312) of the semiconductor component (310); and
wherein the assemblies are arranged at opposite ends of a respective side surface (321) of the heat sink (320), in particular at opposite ends with respect to a flow direction of a cooling fluid through the heat sink (320).

11. The switch arrangement (300) according to claim 8, further comprising at least one clamping element adapted to press one or more of the semiconductor components (310) of the assembly and the further semiconductor components against the heat sink (320).

12. The switch arrangement (300) according to claim 7, further comprising a control board (330), wherein a main extension plane of the control board (330) is oriented perpendicular or at least substantially perpendicular to a main extension plane of the individual semiconductor components (310) of the assembly and the further semiconductor components, wherein respective individual or multiple terminals (313) of the individual semiconductor components (310) of the assembly and the further semiconductor components are connected to the control board (330).

13. The switch arrangement (300) according to claim 12, wherein the second conductor sections (132, 232) of the temperature sensor unit (100) are electrically connected to the control board (330) of the switch arrangement (300).
